(19) United States
(12) Patent Application Publication
(10) Pub. No.: US 2008/0308305 A1
(43) Pub. Date: Dec. 18, 2008

(54) WIRING SUBSTRATE WITH REINFORCING MEMBER

(75) Inventor: Tadahiko KAWABE, Gifu (JP)

Correspondence Address: SUGHRUE-265550, 2100 PENNSYLVANIA AVE. NW, WASHINGTON, DC, 20037-3213, US

(73) Assignee: NGK SPARK PLUG CO., LTD., Nagoya-shi (JP)

(21) Appl. No.: 12/138,859

(22) Filed: Jun. 13, 2008

(30) Foreign Application Priority Data
Jun. 15, 2007 (JP) 2007-158841
Jun. 15, 2007 (JP) 2007-158842

(51) Int. Cl. H05K 1/02

(52) U.S. Cl. 174/255

(57) ABSTRACT

A wiring substrate with a reinforcing member includes: a resin wiring substrate having a substrate principal surface, a substrate rear surface, and substrate side surfaces, forming a rectangular shape having four sides in plan view, and including a resin insulating layer and a conductor layer; and a reinforcing member formed in a rectangular frame shape which surrounds the four sides of the resin wiring substrate, and provided with an inner wall having a depression surface-joined to at least one of the substrate side surfaces, an outer peripheral portion of the substrate principal surface, and an outer peripheral portion of the substrate rear surface.

### CROSS-REFERENCE TO RELATED APPLICATIONS

This application claims the benefit of Japanese Patent Application JP 2007-158841, filed Jun. 15, 2007, and Japanese Patent Application JP 2007-158842, filed Jun. 15, 2007, the entire contents of which are hereby incorporated by reference, the same as if set forth at length.

### FIELD OF THE INVENTION

The present invention relates to the wiring substrate with a reinforcing member including a reinforcing member for preventing the warpage of a resin wiring substrate.

### BACKGROUND OF THE INVENTION

The spread of electronics devices like personal computers or cellular phones is bringing large changes in social structure as the IT revolution. The heart of this technique is the large-scale semiconductor integrated circuit (LSI) technique, and the operating frequency of this LSI (LSI chip) tends to become increasingly high in order to achieve the improvement in computing speed. In addition, an LSI chip is used in the state of being flip-chip connected (so-called the state of a semiconductor package) on a wiring substrate for mounting an LSI, (for example, refer to JP-A-2002-26500 (FIG. 1, etc.)). This LSI chip is formed using a semiconductor material (for example, silicon, etc.) whose thermal expansion coefficient is generally 2.0 ppm/° C. to about 5.0 ppm/° C. On the other hand, the wiring substrate for mounting an LSI is often a resin wiring substrate formed using a resin material whose thermal expansion coefficient is quite larger than the semiconductor material. As an example of this resin wiring substrate, one in which build-up layers are formed on the front surface and rear surface of a core substrate made of a polymeric material is conventionally proposed.

Meanwhile, in recent years, with miniaturization of devices on which a semiconductor package is to be mounted, miniaturization and thinning of the resin wiring substrate are required. However, if the resin wiring substrate is thinned, particularly the thickness of the core substrate is set to, for example, 800 μm or less, degradation of the stiffness of the resin wiring substrate is no longer avoided. In this case, when the solder used for flip-chip connection is cooled, the resin wiring substrate is affected by the thermal stress resulting from a thermal expansion coefficient difference between a chip material and a substrate material, and is apt to warp on the side of a chip mounting surface. As a result, cracking is apt to be caused in a chip junction, or an open failure, etc. is apt to occur. That is, in a case where a semiconductor package is configured using the above LSI chip, a problem that high yield ratio or reliability cannot be realized occurs. Further, if the resin wiring substrate is miniaturized, a problem that the handling ability of the semiconductor package degrades occurs.

In order to solve the above problem, a semiconductor package 100 in which a metallic stiffener 105 is stuck on one surface (a substrate principal surface 102 or a substrate rear surface 103) of a resin wiring substrate 101 using a double-sided adhesive tape 104 (or solder, etc.) is suggested (refer to FIGS. 13 and 14). Thus, since the warpage of the resin wiring substrate 101 is suppressed by the stiffener 105 and cracking is hardly caused in a junction between the resin wiring substrate 101 and an LSI chip 106, the yield ratio becomes high, and the reliability improves. Further, since the stiffness of the semiconductor package 100 becomes high by sticking the stiffener 105, the handling ability of the semiconductor package 100 improves.

### SUMMARY OF THE INVENTION

Meanwhile, since the stiffener 105 has a simple shape (a flat plate shape) which comes into contact with only one surface of the resin wiring substrate 101, it is necessary to make the stiffness of the stiffener itself high in order to give the function to suppress the warpage of the resin wiring substrate 101. Thus, although it is conceivable to make the stiffener 105 thick, the whole semiconductor package 100 becomes thick, which may lead to enlargement of the semiconductor package 100. Consequently, it is indispensable to form the stiffener 105 of a metallic material of high stiffness which is not warped even if being influenced by a stress. However, since the metallic material of high stiffness is generally expensive, the manufacturing cost of the stiffener 105 will rise, and consequently the manufacturing cost of the semiconductor package 100 will rise.

The invention has been made in view of the above problems, and the object thereof is to provide a wiring substrate with a reinforcing member which can improve reliability and handling ability, without increasing the manufacturing cost of the reinforcing member.

Further, in the aforementioned LSI chip 106, the consumption of current tends to become large with the improvement in performance. Therefore, it is necessary to provide a supply path for supply of large current within the resin wiring substrate 101. In addition, the resin wiring substrate 101 has a structure in which build-up layers composed of a resin insulating layer and a conductor layer are stacked on the front and rear surfaces of a core substrate, and the supply path is a path which passes through through-hole conductors which penetrates the core substrate in its thickness direction, a plurality of conductor layers, and via conductors which penetrate the resin insulating layer in its thickness direction.

However, in order to provide the supply path within the resin wiring substrate 101, a large-scale design change should be made. Even if the supply path can be provided, since the conductor layers are made thin with thinning of the resin wiring substrate 101, resistance is large. Further, since it is difficult to increase the external diameter of the through-hole conductors or the via conductors or increase the number thereof because of space, resistance is large. Accordingly, since a voltage drop becomes large even if current is supplied toward the substrate principal surface 102 from the substrate rear surface 103 via the supply path, large current cannot be surely supplied to the LSI chip 106.

Moreover, since the stiffener 105 of the conventional structure is one which has simply the function to reinforce the resin wiring substrate 101, if an additional function is given, it is considered that the stiffener is further highly functionalized.

A preferable aspect of the invention has been made in view of the above problems, and the object thereof is to provide a wiring substrate with a reinforcing member which can supply large current to a conductor layer on the side of a substrate principal surface from a conductor layer on the side of a substrate rear surface, without changing the structure of a resin wiring substrate and which can improve reliability and handling ability, without increasing the manufacturing cost of the reinforcing member.

As a means for solving the above problems, there is a wiring substrate with a reinforcing member including a resin wiring substrate having a substrate principal surface, a substrate rear surface, and substrate side surfaces, forming a rectangular shape having four sides in plan view, and having a structure in which a resin insulating layer and a conductor layer are stacked, and a reinforcing member formed in a rectangular frame shape which surrounds the four sides of the resin wiring substrate, and having a depression surface-joined to at least one of the substrate side surfaces, an outer peripheral portion of the substrate principal surface, and an outer peripheral portion of the substrate rear surface at its inner wall.

Accordingly, according to the invention of the above means, the reinforcing member is surface-joined to at least two surfaces at four sides of the resin wiring substrate. Thereby, since the four sides of the resin wiring substrate can be reinforced surely, the warpage of the resin wiring substrate is suppressed surely. Therefore, since the defects resulting from the warpage of the resin wiring substrate are prevented, the reliability of the wiring substrate with a reinforcing member improves. Further, since the stiffness of the wiring substrate with a reinforcing member becomes high by the surface joining of the reinforcing member to the resin wiring substrate, the handling ability of the wiring substrate with a reinforcing member improves. Moreover, since the reinforcing member has the depression, and has a shape where stiffness is higher than a mere flat plate shape, the need for making the reinforcing member thick or forming the reinforcing member using a material of high cost and high stiffness is obviated. Accordingly, the reliability and handling ability can be improved without increasing the manufacturing cost of the reinforcing member. In a preferable aspect of the invention, in the wiring substrate with a reinforcing member of the above invention, a plate-like connecting terminal piece attached to the reinforcing member along the inside surface or outside surface of the reinforcing member, and coming into contact with a conductor layer of the resin wiring substrate on the side of the substrate principal surface and a conductor layer thereof on the side of the substrate rear surface, thereby electrically connecting the conductor layers, is provided.

Accordingly, according to the preferable aspect of the above invention, the reinforcing member is surface-joining to at least two surfaces at the four sides of the resin wiring substrate. Therefore, it becomes easy to attach the plate-like connecting terminal piece to the reinforcing member along the inside surface or outside surface of the reinforcing member. As a result, the conductor layer on the side of the substrate principal surface, and the conductor layer on the side of the substrate rear surface can be electrically connected by bypassing the outside of the resin wiring substrate. Accordingly, large current can be supplied to the conductor layer on the side of the substrate principal surface via the plate-like connecting terminal piece from the conductor layer on the side of the substrate rear surface without changing the structure of the resin wiring substrate.

The resin wiring substrate which constitutes the wiring substrate with a reinforcing member can be suitably selected in consideration of cost properties, workability, insulating performance, mechanical strength, etc. As the resin wiring substrate, one which has a substrate principal surface, a substrate rear surface, and four substrate side surfaces, forms a rectangular shape having four sides in plan view, and has a structure in which a resin insulating layer and a conductor layer are stacked is used.

The resin insulating layer can be suitably selected in consideration of insulating performance, thermal resistance, moisture resistance, etc. Suitable examples of a polymeric material for forming the resin insulating layer include thermosetting resins, such as epoxy resin, phenol resin, urethane resin, silicone resin, and polyimide resin, and thermoplastic resins, such as polycarbonate resin, acrylic resin, polyacetal resin, and polypropylene resin, etc. In addition, a composite material of these resins and organic fibers such as polyamide fibers or glass fibers (glass woven fabric and non-woven glass fabric), and a resin-resin composite material in which thermosetting resins, such as epoxy resin, is impregnated in three-dimensional net-like fluorine-based resin base material, such as continuous porous PTFE, may be used.

The conductor layer is mainly made of copper, and is formed by a well-known technique, such as a subtractive method, a semi-additive method, or a full additive method. Specifically, for example, a technique, such as etching of a copper foil, electroless copper plating, or electrolytic copper plating is applied. In addition, the conductor layer can be formed by performing etching after a thin film is formed by a technique, such as sputtering or CVD, or the conductor layer can also be formed by printing of conductive paste or the like.

Further, a metal plate (metal core) may be provided in an internal layer in the resin wiring substrate as a core. As examples of the metal which constitutes the metal plate, there are copper, copper alloys, metal simple substances or alloys other than copper, etc. Moreover, the resin wiring substrate may be of a type in which a resin insulating layer and a conductor layer are alternately formed on a core substrate (made of resin).

The reinforcing member which constitutes the wiring substrate with a reinforcing member is surface-joined to at least of the substrate side surfaces, the outer peripheral portion of the substrate principal surface, and the outer peripheral portion of the substrate rear surface. Although the shape of the reinforcing member is not limited particularly but is arbitrary, it is desirable to have a flat surface (inner wall) to be surface-joined to the substrate side surfaces, the outer peripheral portion of the substrate principal surface, and the outer peripheral portion of the substrate rear surface. Accordingly, it is preferable to use, for example, a substantially L-shaped sectional reinforcing member to be surface-joined to the substrate side surfaces, and the outer peripheral portion of the substrate principal surface, a substantially L-shaped sectional reinforcing member to be surface-joined to the substrate side surfaces, and the outer peripheral portion of the substrate rear surface, a substantially U-shaped sectional reinforcing member to be surface-joined to the substrate side surfaces, and the outer peripheral portion of the substrate principal surface, and the outer peripheral portion of the substrate rear surface, etc. Particularly, it is desirable to use a substantially U-shaped sectional reinforcing member to be surface-joined to the substrate side surfaces, the outer peripheral portion of the substrate principal surface, and the outer peripheral portion of the substrate rear surface. Thus, since the stiffness of the reinforcing member becomes higher than a case where a reinforcing member has a substantially L-shaped section, the stiffness of the resin wiring substrate further improves. Further, since the kinds of a forming material for the reinforcing member which can be selected further increases, the reinforcing member can be formed using a lower-cost material, and the manufacturing cost of the reinforcing member is further reduced.

In addition, an example of the substantially U-shaped sectional reinforcing member surface-joined to the substrate side surfaces, the outer peripheral portion of the substrate principal surface, and the outer peripheral portion of the substrate rear surface can include one in which the depression is constituted by a reinforcing member main body capable of coming into surface contact with the substrate side surfaces, a first protruding piece capable of protruding toward the center of the resin wiring substrate from the reinforcing member main body and coming into surface contact with the outer peripheral portion of the substrate principal surface, and a second protruding piece capable of protruding toward the center of the resin wiring substrate from the reinforcing member main body and coming into surface contact with the outer peripheral portion of the substrate rear surface. In this case, preferably, the spacing between the first protruding piece and the second protruding piece is made smaller than the thickness of the resin wiring substrate, and the resin wiring substrate is sandwiched by the first protruding piece and the second protruding piece. Thus, since the resin wiring substrate can be held by three surfaces including the inside surface (inner wall) of the reinforcing member main body, the inside surface (inner wall) of the first protruding piece, and the inside surface (inner wall) of the second protruding piece, thus, the resin wiring substrate can be held more stably. Moreover, even if adhesive is not used, the reinforcing member can be surely joined to the resin wiring substrate. Further, if the adhesive is used, the joining between the resin wiring substrate and the reinforcing member becomes more positive. In addition, in a case where, for example, a semiconductor integrated circuit element is mounted on the side of the substrate principal surface and on the side of the substrate rear surface is connected to a mother board for mounting the resin wiring substrate, it is preferable that the thickness of the second protruding piece be smaller than the thickness of the first protruding piece. Thus, since the spacing between the substrate rear surface and the mother board does not need to become so large even in a case where the reinforcing member is attached to the resin wiring substrate, the portion on the side of the substrate rear surface and the mother board can be easily connected. Further, preferably, the protruding amount of the first protruding piece is set to be larger than the protruding amount of the second protruding piece. Thus, since the stiffness of the reinforcing member becomes higher than a case where the protruding amount of the first protruding piece is below the protruding amount of the second protruding piece, the stiffness of the resin wiring substrate further improves.

Here, as the above semiconductor integrated circuit element, one whose thermal expansion coefficient is less than 5.0 ppm/° C. is used. It is desirable that the thermal expansion coefficient of the semiconductor integrated circuit element is, particularly, 2.0 ppm/° C. or more and less than 5.0 ppm/° C. An example of the semiconductor integrated circuit element can include, a semiconductor integrated circuit element (LSI chip) made of silicon whose thermal expansion coefficient is about 4.0 ppm/° C. Although the size and shape of the semiconductor integrated circuit element are not limited particularly, it is desirable that at least one side is 5.0 mm or more. This is because, if such a large-sized semiconductor integrated circuit element is used, thermal capacity is apt to increase, and the element is easily affected by stress, and therefore, the object of the present invention, which is to be solved by the present invention, is apt to occur. This is because, if such a thin semiconductor integrated circuit element is used, thermal capacity is apt to increase, and the element is easily affected by stress, and therefore, the object of the present invention is apt to occur.

Here, the “thermal expansion coefficient” of the semiconductor integrated circuit element means thermal expansion coefficient in a vertical direction (XY direction) to a thickness direction (Z direction), and indicates a value measured by a TMA (a thermal mechanical analyzer) between 0° C. and 100° C. The “TMA” means an apparatus which performs thermal heat mechanical analysis, for example, an apparatus which is specified in JPCA-BU01.

Preferably, the reinforcing member is made a resin material of higher stiffness than a resin material which constitutes the resin wiring substrate. For example, preferably, the reinforcing member is made of a resin material whose Young's modulus is higher than a resin material which constitutes the resin wiring substrate. Specifically, it is suitable that the Young's modulus of the resin material which constitutes the reinforcing member is 50 GPa or more. This is because, if high stiffness is given to the reinforcing member itself, surface-joining the reinforcing member can give high stiffness to the resin wiring substrate which becomes stronger to the stress to be applied from the outside. Further, this is because, if the reinforcing member having high stiffness is used, sufficiently high stiffness can be given to the resin wiring substrate even if the reinforcing member is made thin, and therefore, thinning of the whole wiring substrate with a reinforcing member will not be obstructed. In addition, if the reinforcing member satisfies the condition that it has higher stiffness than the resin wiring substrate, the reinforcing member may be made of ceramic or metal. However, from the viewpoint of manufacturing cost or weight saving, preferably, the reinforcing member generally be made of a resin material more inexpensive and more lightweight than a ceramic material and a metallic material.

Suitable examples of the resin material which constitutes the reinforcing member include PB resin (polybutene resin), PA resin (polyamide resin), ABS resin (acrylonitrile butadiene styrene copolymer), PBT resin (polybutylene terephthalate), PPS resin (polyphenylene sulfide resin), PI resin (polyimide resin), PC resin (polycarbonate resin), etc. In addition, a composite material of these resins and organic fibers such as polyamide fibers or glass fibers (glass woven fabric and non-woven glass fabric), etc. may be used.

Further, preferably, the reinforcing member has a low thermal expansion coefficient in addition to having high stiffness. It is desirable that thermal expansion coefficient of the reinforcing member is lower than the thermal expansion coefficient of the resin insulating layer, and specifically, 5 ppm/° C. or more and less than 20 ppm/° C.

Although the reinforcing member is surface-joined to the resin wiring substrate, the technique of the surface joining is not limited particularly, and well-known techniques suitable for the properties, shape, etc. of a material which forms the reinforcing member can be adopted. For example, preferably, the inner wall of the depression is surface-joined to at least one of the substrate side surfaces, the outer peripheral portion of the substrate principal surface, and the outer peripheral portion of the substrate rear surface via adhesive. Thus, the reinforcing member can be surely and easily joined to the resin wiring substrate. For example, preferably, the inside surface of the reinforcing member is partially stuck on the plate-like connecting terminal piece via adhesive, and is joined and fixed to at least one of the substrate side surfaces, the outer peripheral portion of the substrate principal surface, and the outer peripheral portion of the substrate rear surface via adhesive. Thus, the plate-like connecting terminal piece can be surely and easily joined to the reinforcing member, and the reinforcing member can be surely and easily joined to the resin wiring substrate. In addition, in a case where the reinforcing member is made of a resin material, the adhesive includes acrylic adhesive, epoxy-based adhesive, cyanoacrylate adhesive, rubber-based adhesive, etc. Further, in a case where the reinforcing member is made of a metallic material or a ceramic material, the adhesive includes adhesive which contains polymers as its principal ingredient.

In addition, preferably, the reinforcing member is composed of a plurality of rail members, and is formed in a rectangular frame shape by connecting the plurality of rail members to each other at their respective ends. Further, the reinforcing member may be a rail-like member, and may be formed in a rectangular frame shape by bending three bent portions provided in the rail-like member. Since structure becomes simpler in the case where the reinforcing member is made of a plurality of rail members than in the case where the reinforcing member is a rail-like member, the manufacturing cost of the reinforcing member made of a plurality of rail members is further reduced. On the other hand, if the reinforcing member is a rail-like member, since the process of connecting a plurality of rail members to each other becomes unnecessary, manufacture of the reinforcing member becomes easy. Here, although the shape of each of the rail members in plan view is basically arbitrary, the rail members are formed in such a shape which becomes a rectangular frame shape when being connected to each other, for example, is substantially rod-shaped in plan view (substantially I-shaped in plan view), substantially L-shaped in plan view, substantially U-shaped in plan view, etc. In addition, if the rail members are formed in the same shape, since all the rail members can be formed in the same facility, the manufacturing cost of the reinforcing member can be further reduced.

The method of manufacturing the reinforcing member includes a method of performing laser processing on a resin sheet to cut out a rectangular frame-shaped reinforcing member, a method of cutting out a plurality of rail members by laser processing on a resin sheet, and joining the rail members to each other at their respective ends to obtain a rectangular frame-shaped reinforcing member, a method of blanking a resin sheet to obtain a reinforcing member, a method of pouring a resin member into a mold to cure the resin member to obtain a reinforcing member, and a method of obtaining a reinforcing member by printing.

The reinforcing member may include a conductor post which electrically connects a portion on the side of the inside surface and a portion on the side of the outside surface, and a terminal pad arranged on the outside surface and connected to the conductor post, and the plate-like connecting terminal piece provided in the preferable aspect of the invention may be connected to the end of the conductor post on the side of the inside surface. Thus, an electronic component can be mounted on the outside surface of the reinforcing member. If the electronic component has a defect in a case where the electronic component is mounted on the resin wiring substrate, not only the electronic component but the resin wiring substrate will become useless. On the other hand, in a case where an electronic component is mounted on the reinforcing member as mentioned above, it is only necessary to remount the electronic component. Therefore, the resin wiring substrate does not become useless.

The plate-like connecting terminal piece which constitutes the wiring substrate with a reinforcing member in the preferable aspect of the invention comes into contact with the conductor layer of the resin wiring substrate on the side of the substrate principal surface and the conductor layer thereof on the side of the substrate rear surface, thereby electrically connecting the conductor layers. Although the plate-like connecting terminal piece may be attached to the reinforcing member along the inside surface of the reinforcing member, or may be attached to the reinforcing member along the outside surface of the reinforcing member, it is preferable that the plate-like connecting terminal piece be attached to the reinforcing member along the inside surface of the reinforcing member. Thus, since the plate-like connecting terminal piece is protected by the reinforcing member, the short-circuiting caused as the plate-like connecting terminal piece comes into contact with other conductive members can be prevented. Further, damage, corrosion, etc. of the plate-like connecting terminal piece can be prevented.

As the material which forms the plate-like connecting terminal piece provided in the preferable aspect of the invention, a material (for example, conductive metallic material) having conductivity is desirable. For example, iron, silver, copper, copper alloys, nickel, nickel alloys, tin, tin alloys, Fe—Ni-based alloys, such as invar (Fe—Ni-based alloys, 36% Ni), so-called 42 alloys (Fe—Ni-based alloys, 42% Ni), and so-called 50 alloys (Fe—Ni-based alloys, 50% Ni), tungsten, molybdenum, etc. are suitably used.

Preferably, the plate-like connecting terminal piece provided in the preferable aspect of the invention is made a conductive metallic of higher stiffness than the resin wiring substrate. For example, it is preferable that the plate-like connecting terminal piece be made of a conductive metallic material whose Young's modulus is higher than a resin material which constitutes the resin wiring substrate. Specifically, it is suitable that the Young's modulus of the conductive metallic material which constitutes the reinforcing member is 50 GPa or more. This is because, if high stiffness is given to the plate-like connecting terminal piece itself, both the reinforcing member and the plate-like connecting terminal piece can give high stiffness to the resin wiring substrate which becomes stronger to the stress to be applied from the outside.

Further, preferably, the plate-like connecting terminal piece provided in the preferable aspect of the invention has a low thermal expansion coefficient in addition to having high stiffness. It is desirable that thermal expansion coefficient of the plate-like connecting terminal piece is lower than the thermal expansion coefficient of the resin wiring substrate, and specifically, 1 ppm/° C. or more and less than 20 ppm/° C.

Here, the plate-like connecting terminal piece is manufactured by a well-known technique. For example, the plate-like connecting terminal piece can be manufactured by processing a metal plate to form a punched hole, a recess, etc., if required. As a processing method in this case, chemical processing methods, such as etching, may be used and mechanical processing, such as cutting and punching, may be used.

In addition, preferably, the plate-like connecting terminal piece provided in the preferable aspect of the invention is attached to the reinforcing member along the inside surface of the reinforcing member, a portion of the inside surface of the reinforcing member is formed with an accommodating recess for accommodating the plate-like connecting terminal piece, and the depth of the accommodating recess is equal to the thickness of plate-like connecting terminal piece. If such structure is provided, the inside surface of the reinforcing member and the surface on the side of plate-like connecting terminal piece on the side of an opening edge of the accommodating recess become flush when the plate-like connecting terminal piece is accommodated in the accommodating recess. Thereby, even in a case where the plate-like connecting terminal piece is arranged between the resin wiring substrate and the reinforcing member, the contact area between the inside surface of the reinforcing member and the surface (at least one of the substrate side surfaces, the substrate principal surface, and the substrate rear surface) of the resin wiring substrate can be secured. Therefore, the four sides of the resin wiring substrate can be reinforced more surely. Further, since the plate-like connecting terminal piece is held in a state of being accommodated in the accommodating recess, alignment is easy. In addition, if adhesive is poured into the accommodating recess, the alignment of the plate-like connecting terminal piece become surer.

Further, preferably, the plate-like connecting terminal piece provided in the preferable aspect of the invention comes into contact with conductor layers for a power source on the side of the substrate principal surface and the substrate rear surface, or the invention comes into contact with conductor layers for grounding on the side of the substrate principal surface and the substrate rear surface, thereby electrically connecting both of them. Thus, since large current can be made flow through the conductor layers for a power source or the conductor layers for grounding via the plate-like connecting terminal piece, a semiconductor integrated circuit element mounted on at least one of the substrate principal surface and substrate rear surface can be operated surely.

Moreover, more preferably, a plurality of the plate-like connecting terminal pieces are provided, and the reinforcing member is made of an insulated resin material. Thus, larger current can be made to flow via the plurality of plate-like connecting terminal pieces. Further, since the reinforcing member is made of an insulated resin material, the short-circuiting of a supply path which passes through each of the plate-like connecting terminal pieces can be prevented.

Further, preferably, in a case where the reinforcing member is constituted by a reinforcing member main body capable of coming into surface contact with the substrate side surfaces, a first protruding piece capable of protruding toward the center of the resin wiring substrate from the reinforcing member main body and coming into surface contact with the outer peripheral portion of the substrate principal surface, and a second protruding piece capable of protruding toward the center of the resin wiring substrate from the reinforcing member main body and coming into surface contact with the outer peripheral portion of the substrate rear surface, the plate-like connecting terminal piece is constituted by a terminal piece main body capable of coming into contact with the substrate side surfaces and the reinforcing member main body, a first protruding portion capable of protruding toward the center of the resin wiring substrate from the terminal piece main body and coming into surface contact with the outer peripheral portion of the substrate principal surface and the first protruding piece, and a second protruding portion capable of protruding toward the center of the resin wiring substrate from the terminal piece main body and coming into surface contact with the outer peripheral portion of the substrate rear surface and the second protruding piece. The protruding amount of the first protruding portion is set to be larger than the protruding amount of the first protruding piece, and the protruding amount of the second protruding portion is set to be larger than the protruding amount of the second protruding piece. Thus, not only the conductor layer on the side of the substrate principal surface at the outer peripheral portion of the substrate principal surface, but the conductor layer on the side of the substrate principal surface at the center of the substrate principal surface can be brought into contact with the first protruding portion. Similarly, not only the conductor layer on the side of the substrate rear surface at the outer peripheral portion of the substrate rear surface, but the conductor layer on the side of the substrate rear surface at the center of the substrate rear surface can be brought into contact with the second protruding portion. Consequently, the conductor layer on the side of the substrate principal surface and the conductor layer on the side of the substrate rear surface can be more surely connected via the plate-like connecting terminal piece.

### BRIEF DESCRIPTION OF THE DRAWINGS

FIG. 1 is a schematic perspective view showing a semiconductor package in this embodiment.

FIG. 2 is a schematic perspective view showing the semiconductor package.

FIG. 3 is a schematic sectional view showing the semiconductor package.

FIG. 4 is a sectional view of main parts showing the semiconductor package.

FIG. 5 is a schematic perspective view showing a state when a stiffener is attached to a resin wiring substrate.

FIG. 6 is a schematic perspective view showing the configuration of the stiffener.

FIG. 7 is a schematic sectional view showing the relationship between the stiffener and plate-like connecting terminal pieces.

FIG. 8 is a front view showing the vicinity of an accommodating recess in the stiffener.

FIG. 9 is a sectional view of main parts showing a semiconductor package in another embodiment.

FIG. 10 is a sectional view of main parts showing a semiconductor package in still another embodiment.

FIG. 11 is a sectional view of main parts showing a semiconductor package in a still further embodiment.

FIG. 12 is a sectional view of main parts showing a semiconductor package in a still further embodiment.

FIG. 13 is a schematic perspective view showing a semiconductor package in a conventional technique.

FIG. 14 is a schematic sectional view showing the semiconductor package in the conventional technique.

FIG. 15 is a schematic perspective view showing a semiconductor package in a still further embodiment.

FIG. 16 is an explanatory view showing the configuration of a stiffener in the still further embodiment.

### REFERENCE NUMERALS

11, 11A, 11B, 11C, 11D: WIRING SUBSTRATE AS WIRING SUBSTRATE WITH REINFORCING MEMBER
31, 271 31A, 31B, 31C, 91: STIFFENER AS REINFORCING MEMBER
32, 92, 121, 131: OUTSIDE SURFACE OF REINFORCING MEMBER
33, 93, 132: INSIDE SURFACE OF REINFORCING MEMBER
34: DEPRESSION
35, 36: RAIL MEMBER
37: REINFORCING MEMBER MAIN BODY
38, 111, 122: FIRST PROTRUDING PIECE
39, 112: SECOND PROTRUDING PIECE
40: RESIN WIRING SUBSTRATE
41: SUBSTRATE PRINCIPAL SURFACE
42: SUBSTRATE REAR SURFACE
43: SUBSTRATE SIDE SURFACE
50: ADHESIVE
53, 54: RESIN INSULATING LAYER
55: CONDUCTOR LAYER
70: ACCOMMODATING RECESS
71: PLATE-LIKE CONNECTING TERMINAL PIECE FOR POWER SOURCE AS PLATE-LIKE CONNECTING TERMINAL PIECE
72: PLATE-LIKE CONNECTING TERMINAL PIECE FOR GROUNDING AS PLATE-LIKE CONNECTING TERMINAL PIECE
73: CONDUCTORS FOR POWER SOURCE AS CONDUCTOR LAYER ON THE SIDE OF SUBSTRATE PRINCIPAL SURFACE AND CONDUCTOR LAYER ON THE SIDE OF SUBSTRATE REAR SURFACE
74: CONDUCTORS FOR GROUNDING AS CONDUCTOR LAYER ON THE SIDE OF SUBSTRATE PRINCIPAL SURFACE AND CONDUCTOR LAYER ON THE SIDE OF SUBSTRATE REAR SURFACE
75: TERMINAL PIECE MAIN BODY
76: FIRST PROTRUDING PIECE
77: SECOND PROTRUDING PIECE
82, 133: THROUGH-HOLE CONDUCTOR AS CONDUCTOR POST
83, 134: TERMINAL PAD
272: RAIL-LIKE MEMBER
273: BENT PORTION
L1: PROTRUDING AMOUNT OF FIRST PROTRUDING PORTION
L2: PROTRUDING AMOUNT OF SECOND PROTRUDING PORTION

### DETAILED DESCRIPTION OF THE INVENTION

Hereinafter, one embodiment of the invention will be described in detail with reference to the drawings.

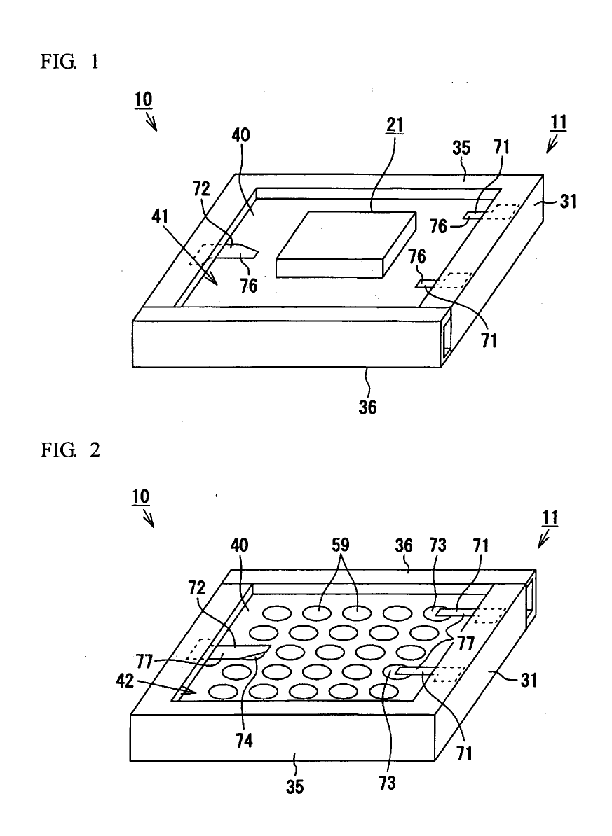

As shown in FIGS. 1 to 4, a semiconductor package 10 of this embodiment is a PGA (pin grid array) composed of a wiring substrate 11 with a stiffener (wiring substrate with a reinforcing member), and an LSI chip 21 which is a semiconductor integrated circuit element. In addition, the form of the semiconductor package 10 is not limited only to the PGA. For example, the semiconductor package may be a BGA (ball grid array), an LGA (land grid array), etc. The LSI chip 21 has a rectangular flat shape of 15.0 mm (length)×15.0 mm (width)×0.8 mm (thickness), and is made of silicon whose thermal expansion coefficient is 4.2 ppm/° C. A circuit element which is not shown is formed on a surface layer on the side of a bottom surface 24 of the LSI chip 21. Further, a plurality of surface connection terminals 22 are provided in a grid pattern on the side of the bottom surface 24 of the LSI chip 21.

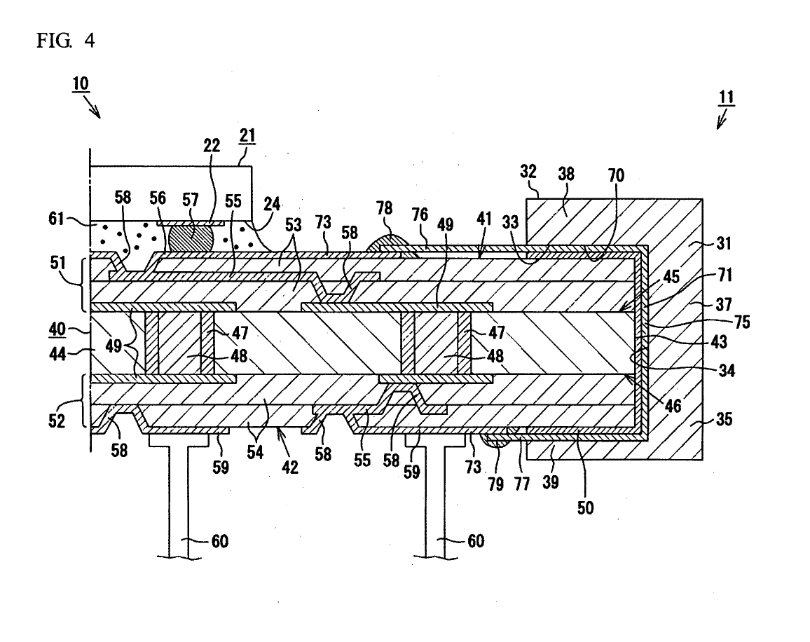

On the other hand, the wiring substrate 11 with a stiffener includes a resin wiring substrate 40, and a stiffener 31 for a wiring substrate (hereinafter referred to as a “stiffener”) which is a reinforcing member. Furthermore, in a preferable aspect of the invention, the wiring substrate 11 with a stiffener includes the resin wiring substrate 40, the stiffener 31 which is a reinforcing member, and three plate-like connecting terminal pieces (specifically, two plate-like connecting terminal pieces 71 for a power source, and one plate-like connecting terminal piece 72 for grounding). The resin wiring substrate 40 has one substrate principal surface 41, a substrate rear surface 42, and four substrate side surfaces 43, and forms a rectangular shape having four sides in plan view. Further, the resin wiring substrate 40 has a substantially rectangular plate-like core substrate 44 made of glass epoxy, and is a build-up multilayer wiring substrate which has a first build-up layer 51 on a core principal surface 45 (top surface in FIG. 4) of the core substrate 44, and similarly has a second build-up layer 52 on a core rear surface 46 (bottom surface in FIG. 4) of the core substrate 44.

As shown in FIG. 4, the core substrate 44 of this embodiment has a substantially rectangular shape in plan view with 50.0 mm (length)×50.0 mm (width)×0.4 mm (thickness). The core substrate 44 has a thermal expansion coefficient in a planar direction (XY direction) of about 10 to 30 ppm/° C. (specifically 18 ppm/° C.). In addition, thermal expansion coefficient of the core substrate 44 means an average value of measurement values between 0° C. and a glass transition temperature (Tg). Further, a plurality of through-hole conductors 47 which pass through the core principal surface 45 and the core rear surface 46 are formed in the core substrate 44. The through-hole conductors 47 electrically connect the portions of the core substrate 44 on the side of the core principal surface 45 and on the side of the core rear surface 46. In addition, the insides of the through-hole conductors 47 are buried with, for example, blocking bodies 48, such as epoxy resin. Also, lid-like conductors 49 made of a copper plating layer are formed in openings in the through-hole conductors 47, and as a result, the through-hole conductors 47 are blocked.

As shown in FIG. 4, the first build-up layer 51 formed on the core principal surface 45 of the core substrate 44 has a structure in which two resin insulating layers 53 made of thermosetting resin (epoxy resin), and a conductor layer 55 made of copper are stacked alternately. In this embodiment, thermal expansion coefficient of the resin insulating layers 53 has 10 to 60 ppm/° C. (specifically about 20 ppm/° C.). In addition, thermal expansion coefficient of the resin insulating layers 53 means an average value of measurement values between 0° C. and a glass transition temperature (Tg). A plurality of via conductors 58 to be connected to the conductor layer 55 are formed in each of the resin insulating layers 53. In addition, the via conductors 58 are conformal vias (vias of a form in which copper plating is not buried completely) formed by electrolytic copper plating. Further, a plurality of terminal pads 56 are formed in an array pattern on the surface of the second resin insulating layer 53. Moreover, almost the whole surface of the second resin insulating layer 53 is covered with solder resist (not shown). Openings (not shown) through which the terminal pads 56 are exposed are formed in predetermined spots of the solder resist, and a plurality of solder bumps 57 are disposed on the surfaces of the terminal pads 56. The solder bumps 57 are electrically connected to the surface connection terminals 22, respectively, of the LSI chip 21. That is, the LSI chip 21 is mounted on the side of the substrate principal surface 41 of the resin wiring substrate 40. Further, an under-filling material 61 made of thermosetting resin is filled into a gap between the LSI chip 21 and the resin wiring substrate 40.

As shown in FIG. 4, the second build-up layer 52 formed on the core rear surface 46 of the core substrate 44 has almost the same structure as the above-mentioned first build-up layer 51. That is, the second build-up layer 52 has a structure in which two resin insulating layers 54 made of thermosetting resin (epoxy resin) and a conductor layer 55 are stacked alternately, and thermal expansion coefficient of the resin insulating layers 54 has 10 to 60 ppm/° C. (specifically about 20 ppm/° C.). Further, a plurality of via conductors 58 to be connected to the conductor layer 55 are formed in each of the resin insulating layers 54. In addition, the via conductors 58 are conformal vias formed by electrolytic copper plating. Further, a plurality of pads 59 for PGA to be electrically connected to the conductor layer 55 are formed on the bottom surface of the second resin insulating layer 54. Moreover, almost the whole bottom surface of the second resin insulating layer 54 is covered with solder resist (not shown). Openings (not shown) through which the pads 59 for PGA are exposed are formed in predetermined spots of the solder resist. On the surfaces of the pads 59 for PGA, a plurality of pins 60 for electric connection with a mother board which is not shown are joined by soldering. Also, the wiring substrate 11 with a stiffener shown in FIGS. 1 to 4 is mounted on the mother board which is not shown by the pins 60.

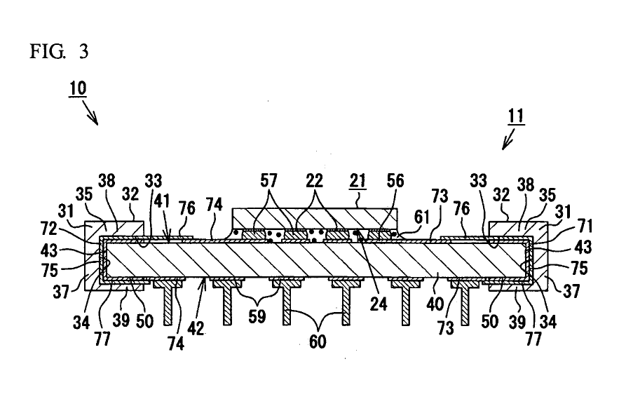

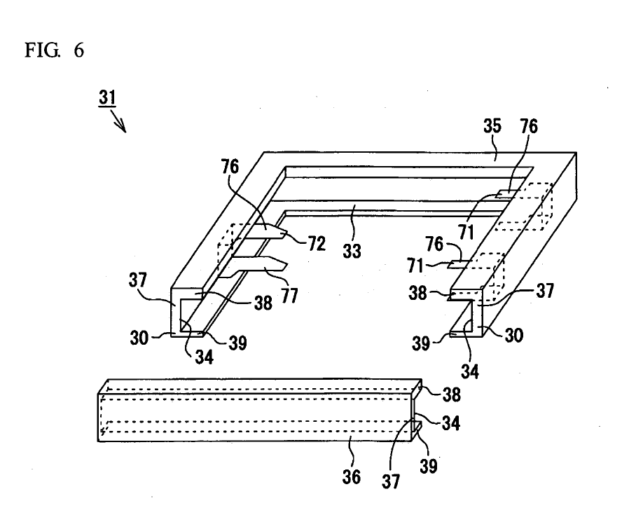

As shown in FIGS. 1 to 8, the stiffener 31 is an annular resin member which surrounds four sides (namely, sides which constitute the four substrate side surfaces 43) of the resin wiring substrate 40. The stiffener 31 of this embodiment has a substantially rectangular shape in plan view with a 52.0 mm (length)×52.0 mm (width)×2.0 mm (thickness). In addition, since the area of the surface (top surface in FIG. 3) of the stiffener 31 is 588 mm² and the area of the substrate principal surface 41 of the resin wiring substrate 40 is 2500 mm², the area of the surface of the stiffener 31 becomes about 24% of the area of the substrate principal surface 41. The stiffener 31 is formed of a resin material (polybutene resin in this embodiment) with higher stiffness than a resin material (glass epoxy and epoxy resin in this embodiment) which constitutes the resin wiring substrate 40 (the core substrate 44 and the build-up layers 51 and 52). Thereby, the thermal expansion coefficient of the stiffener 31 is set to a value smaller than thermal expansion coefficient (about 20 ppm/° C.) of the resin insulating layers 53 and 54, and specifically set about 15 ppm/° C. Further, the Young's modulus of the stiffener 31 is set to a value larger than the Young's modulus of the resin wiring substrate 40, and is set to about 50 GPa.

As shown in FIGS. 1, 2, 5, and 6, the stiffener 31 is composed of consists of two rail members (specifically rail member 35 having a substantially U shape in plan view, and a rail member 36 having a substantially cylindrical shape in plan view). The rail members 35 and 36 are connected to each other at their respective ends, thereby forming the rectangular frame-shaped stiffener 31.

Further, as shown in FIGS. 3 to 8, the stiffener 31 (rail members 35 and 36) has an inside surface 33 and an outside surface 32, and is formed in a substantially U-shaped section which has a depression 34 at its one side surface by a reinforcing member main body 37, a first protruding piece 38, and a second protruding piece 39. The reinforcing member main body 37 is arranged parallel to the substrate side surfaces 43, and is adapted to be able to come into surface contact with the substrate side surfaces 43. The first protruding piece 38 is adapted to be able to protrude toward the center of the resin wiring substrate 40 from a first end (upper end in FIG. 4) of the reinforcing member main body 37 so as to come into surface with an outer peripheral portion (namely, a region except a die area which is a mounting area of the LSI chip 21) of the substrate principal surface 41. The second protruding piece 39 is adapted to be able to protrude toward the center of the resin wiring substrate 40 from a second end (lower end in FIG. 4) of the reinforcing member main body 37 so as to come into surface with an outer peripheral portion (namely, a region except the area where the pins 60 exist) of the substrate rear surface 42. In addition, the width (height from the upper end to the lower end in FIG. 4) of the reinforcing member main body 37 is set to 2.0 mm in this embodiment. The protruding lengths (protruding amounts) of the first protruding piece 38 and the second protruding piece 39 are set to be equal to each other, and are set to about 2.0 mm in this embodiment. Further, the spacing between the first protruding piece 38 and the second protruding piece 39 is a little larger than the thickness of the resin wiring substrate 40, and is set to 0.8 mm in this embodiment. Moreover, the thicknesses of the reinforcing member main body 37 and the first protruding piece 38 are set so that the stiffener 31 can obtain a desired stiffness, and are set to 0.5 mm or more and 1.5 mm or less (1.0 mm in this embodiment). On the other hand, the thickness of the second protruding piece 39 is set to be smaller than the thickness of the reinforcing member main body 37 and the first protruding piece 38 in order to facilitate the connections between the pins 60 on the side of the resin wiring substrate 40, and the mother board, and is set to 0.05 mm or more and 0.5 mm or less (0.1 mm or more and 0.2 mm or less in this embodiment).

Also, as shown in FIGS. 3 and 4, an inner wall 33 of the depression 34 is surface-joined (joined and fixed) to the substrate side surfaces 43, the outer peripheral portion of the substrate principal surface 41, and the outer peripheral portion of the substrate rear surface 42 via adhesive 50. In addition, the adhesive 50 of this embodiment is an epoxy-based adhesive.

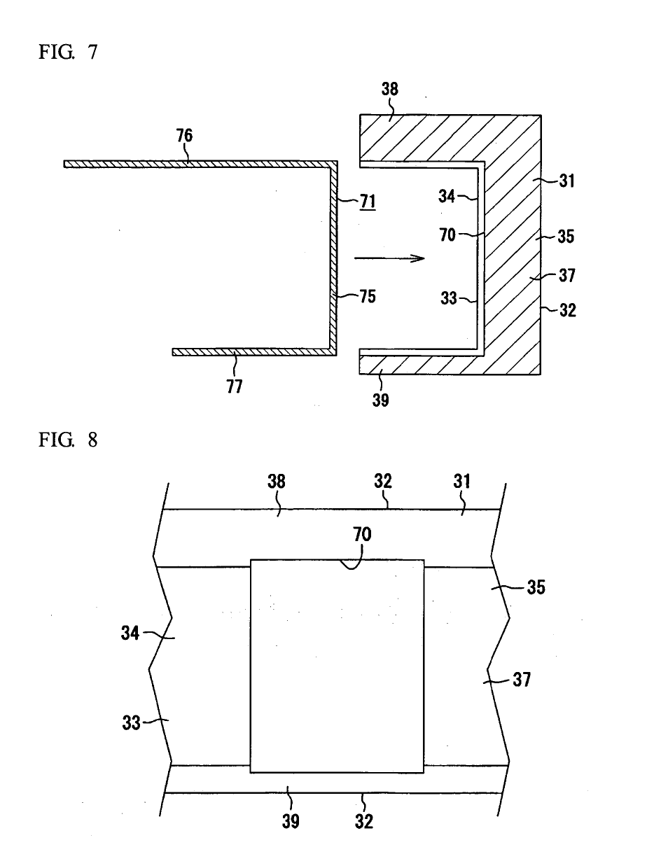

As shown in FIGS. 1 to 7, each of the plate-like connecting terminals pieces 71 and 72 provided in the preferable aspect of the invention is attached to the stiffener 31 along the inside surface 33 of the stiffener 31 (specifically the rail member 35). Specifically, the inside surface 33 of the rail member 35 is formed with a plurality of accommodating recesses 70 (refer to FIGS. 7 and 8), and the plate-like connecting terminal pieces 71 and 72 are accommodated within the accommodating recesses 70, respectively. In addition, the accommodating recesses 70 are arranged away from each other in the rail member 35. Further, the depth of the accommodating recesses 70 is almost equal to the thickness of the plate-like connecting terminal pieces 71 and 72, and the width of the accommodating recesses 70 is almost equal to the width (2 mm or more and 5 mm or less in this embodiment) of the plate-like connecting terminal pieces 71 and 72.

Each of the plate-like connecting terminal pieces 71 and 72 provided in the preferable aspect of the invention is made of a conductive metallic material (copper and copper conductor metal in this embodiment) with higher stiffness than the resin material (glass epoxy and epoxy resin in this embodiment) which constitutes the resin wiring substrate 40 (the core substrate 44 and the build-up layers 51 and 52), and is formed in a substantially U-shaped cross-section by bending a metal plate. Thereby, thermal expansion coefficient of each of the plate-like connecting terminal pieces 71 and 72 is set to a value smaller than thermal expansion coefficient (18 ppm/° C.) of the core substrate 44, or thermal expansion coefficient (about 20 ppm/° C.)) of the resin insulating layers 53 and 54, and specifically set to 16.8 ppm/° C. Further, the Young's modulus of each of the plate-like connecting terminal pieces 71 and 72 is set to a value larger than the Young's modulus of the resin wiring substrate 40, and is set to about 130 GPa.

As shown in FIGS. 3, 4, 7, etc., each of the plate-like connecting terminal pieces 71 and 72 provided in the preferable aspect of the invention is constituted by a terminal piece main body 75, a first protruding portion 76, and a second protruding portion 77. The terminal piece main body 75 is arranged parallel to the substrate side surfaces 43 and the reinforcing member main body 37, and is adapted to be able to come into surface contact with the substrate side surfaces 43 and the reinforcing member main body 37 (bottom surface of one accommodating recess 70). The first protruding portion 76 is adapted to be able to protrude toward the center of the resin wiring substrate 40 from a first end (upper end in FIG. 4) of the terminal piece main body 75 so as to come into surface with the outer peripheral portion of the substrate principal surface 41, and the first protruding piece 38 (bottom surface of the accommodating recess 70). The second protruding portion 77 is adapted to be able to protrude toward the center of the resin wiring substrate 40 from a second end (lower end in FIG. 4) of the terminal piece main body 75 (in the same direction as the first protruding portion 76) so as to come into surface with the outer peripheral portion of the substrate rear surface 42, and the second protruding piece 39 (bottom surface of the accommodating recess 70). In addition, the width of the terminal piece main body 75 (height from the upper end to the lower end in FIG. 4), i.e., the spacing between the first protruding portion 76 and the second protruding portion 77, is set to about 0.8 mm in this embodiment. The protruding amount of the first protruding portion 76 is set to be larger than the protruding amount of the first protruding piece 38, and the protruding amount of the second protruding portion 77 is set to be larger than the protruding amount of the second protruding piece 39. Moreover, the thicknesses of the terminal piece main body 75, the first protruding portion 76, and the second protruding portion 77 are set to about 0.1 mm in this embodiment.

As shown in FIGS. 3, 4, etc., each of the plate-like connecting terminal pieces 71 and 72 provided in the preferable aspect of the invention is stuck on the inside surface of each of the accommodating recesses 70 via adhesive. In addition, the adhesive to be applied to the inside surfaces of the accommodating recesses 70 is the same as the adhesive 50 to be applied to the depression 34 of the stiffener 31.

Further, each of the plate-like connecting terminal pieces 71 and 72 provided in the preferable aspect of the invention comes into contact with the conductor layer of the resin wiring substrate 40 on the side of the substrate principal surface 41 and the conductor layer thereof on the side of the substrate rear surface 42, thereby electrically connecting the conductor layers. Specifically, each plate-like connecting terminal piece 71 for a power source comes into contact with a conductor layer 73 for a power source connected to terminal pads 56 on the substrate principal surface 41, and a conductor layer 73 for a power source connected to the pads 59 for PGA on the substrate rear surface 42, thereby electrically connecting both the conductor layers 73 for a power source. In detail, a distal end of the first protruding portion 76 of the plate-like connecting terminal piece 71 for a power source is electrically connected to the conductor layer 73 for a power source formed on the substrate principal surface 41 via solder 78 (refer to FIG. 4). On the other hand, a distal end of the second protruding portion 77 of the plate-like connecting terminal piece 71 for a power source is electrically connected to the conductor layer 73 for a power source formed on the substrate rear surface 42 via solder 79 (refer to FIG. 4). That is, the plate-like connecting terminal piece 71 for a power source constitutes a bypass path of a supply path which supplies a current to the LSI chip 21 via the pads 59 (conductor layer 73 for a power source) for PGA, the via conductors 58, the conductor layer 55, the through-hole conductors 47, the terminal pads 56 (conductor layer 73 for a power source), etc.

As shown in FIGS. 3 and 4, the plate-like connecting terminal piece 72 for grounding provided in the preferable aspect of the invention comes into contact with the conductor layer 74 for grounding connected to the terminal pads 56 on the substrate principal surface 41, and the conductor layer 74 for grounding connected to the pads 59 for PGA on the substrate rear surface 42, thereby electrically connecting the both the conductor layers 74 for grounding. In detail, a distal end of the first protruding portion 76 of the plate-like connecting terminal piece 72 for grounding is electrically connected to the conductor layer 74 for grounding formed on the substrate principal surface 41 via solder (not shown). On the other hand, a distal end of the second protruding portion 77 of the plate-like connecting terminal piece 72 for grounding is electrically connected to the conductor layer 74 for grounding formed on the substrate rear surface 42 via solder (not shown). That is, the plate-like connecting terminal piece 72 for grounding constitutes a bypass path of a path which passes through the pads 59 (conductor layer 74 for grounding) for PGA, the via conductors 58, the conductor layer 55, the through-hole conductors 47, the terminal pads 56 (conductor layer 74 for grounding), etc.

Next, a manufacturing method of the semiconductor package 10 of this embodiment will be described.

First, the resin wiring substrate 40 is manufactured and prepared in advance by a conventionally well-known technique. The resin wiring substrate 40 is manufactured as follows. First, a copper-clad stack (not shown) in which copper foils are stuck on both sides of a base material with a 50.0 mm (length)×50.0 mm (width)×0.4 mm (thickness) is prepared. Also, laser boring is performed using a YAG laser or a CO2 laser, thereby forming a through hole which passes through the copper-clad stack in advance in a given position. Next, after the through-hole conductors 47 are formed by performing electroless copper plating and electrolytic copper plating according to a conventionally well-known technique, the blocking bodies 48 are filled into the through-hole conductors 47. Moreover, after copper plating is performed on both the sides of the copper-clad stack, the copper foils of both the sides of the copper-clad stack are further etched, thereby patterning the lid-like conductors 49. Specifically, after the electroless copper plating, exposure and development are performed and, thereby forming plating resist of a prescribed pattern. In this state, after electrolytic copper plating is performed by using the electroless copper plating layer as a common electrode, the resist is first melted and removed, and an unnecessary electroless copper plating layer is then removed by etching. As a result, the core substrate 44 is obtained.

Next, a photosensitive epoxy resin is deposited on the core principal surface 45 and the core rear surface 46 of the core substrate 44, and exposure and development is performed, thereby forming the first resin insulating layers 53 and 54 (40 μm in thickness) which have blind holes in positions where the via conductors 58 are to be formed. Moreover, electrolytic copper plating is performed according to a conventional well-known technique (for example, a semi-additive method), thereby forming the via conductors 58 inside the blind holes, and forming the conductor layers 55 on the resin insulating layers 53 and 54.

Next, a photosensitive epoxy resin is deposited on the first resin insulating layers 53 and 54, and exposure and development is performed, thereby forming the second resin insulating layers 53 and 54 (40 μm in thickness) which have blind holes in positions where the via conductors 58 are to be formed. Moreover, electrolytic copper plating is performed according to a conventional well-known technique, thereby forming the via conductors 58 inside the blind holes. Moreover, the terminal pads 56 (and further the conductor layer 73 for a power source and the conductor layer 74 for grounding in the preferable aspect of the invention) are formed on the second resin insulating layer 53, and the pads 59 (and further the conductor layer 73 for a power source and the conductor layer 74 for grounding in the preferable aspect of the invention) for PGA are formed on the second resin insulating layers 54.

Thereafter, solder resist is formed on the second resin insulating layers 53 and 54. Next, exposure and development are performed in a state where a predetermined mask is arranged, thereby patterning openings which expose the terminal pads 56 or the pads 59 (and further the conductor layer 73 for a power source and the conductor layer 74 for grounding in the preferable aspect of the invention) for PGA in the solder resist. As a result, a desired resin wiring substrate 40 having the build-up layers 51 and 52 on both sides thereof is completed.

Thereafter, the substantially semispherical solder bumps 57 are formed on the plurality of terminal pads 56 in the resin wiring substrate 40. The technique of forming the solder bumps 57 is not limited particularly, but a well-known technique, such as a printing method or an electroplating method, can be adopted. Next, the pins 60 are joined to the surfaces of the pads 59 for PGA by soldering. Thereafter, the LSI chip 21 is placed on the substrate principal surface 41 of the resin wiring substrate 40. At this time, the surface connection terminals 22 on the side of LSI chip 21, and the terminal pads 56 on the side of the resin wiring substrate 40 are aligned with one another. Then, each of the surface connection terminals 22 and each of the terminal pads 56 are joined by heating each of the solder bumps 57 to a temperature of around 200° C. to reflow it. Thereafter, thermosetting resin to be the under-filling material 61 is filled into and thermally cured in the gap between the LSI chip 21 and the resin wiring substrate 40.

Further, the stiffener 31 for reinforcing the resin wiring substrate 40 is manufactured and is prepared in advance. The stiffener 31 is manufactured, for example, as follows. First, a cavity of the same shape and volume as the rail member 35 having a substantially U shape in plan view is formed inside by joining a first mold (not shown) and a second mold (not shown). In this state, after polybutene resin having thermoplasticity is filled into the cavity while being heated, and is then cooled, the rail member 35 is molded. Thereafter, if the first mold and the second mold are separated from each other, the molded rail member 35 is unloaded. Similarly a cavity of the same shape and volume as the rail member 36 having a substantially rod shape in plan view is formed inside by joining a third mold (not shown) and a fourth mold (not shown). In this state, after polybutene resin is filled into the cavity while being heated, and is then cooled, the rail member 36 is formed. Thereafter, if the third mold and the fourth mold are separated from each other, the molded rail member 36 is unloaded.

Moreover, in the preferable aspect of the invention, each of the plate-like connecting terminal pieces 71 and 72 is manufactured, and is prepared in advance. The plate-like connecting terminal pieces 71 and 72 provided in the preferable aspect of the invention are manufactured, for example, as follows. First, metal plates (a copper plate and a conductor metal plate in this embodiment) to be the plate-like connecting terminal pieces 71 and 72 afterward are arranged on a lower die (not shown) of a blanking die. Then, an upper die of the blanking die is lowered. At this time, the metal plates are blanked, thereby forming intermediate products of the plate-like connecting terminal pieces 71 and 72. Thereafter, if the intermediate products of the plate-like connecting terminal pieces 71 and 72 are bent in a predetermined spot and are formed in a substantially U-shaped cross-section, the plate-like connecting terminal pieces 71 and 72 are completed.

In the preferable aspect of the invention, next, adhesive is applied to each of the accommodating recesses 70 of the rail member 35, and the plate-like connecting terminal pieces 71 and 72 are inserted into the accommodating recesses 70, respectively. In this state, if the adhesive is dried and cured, the plate-like connecting terminal pieces 71 and 72 are attached to the rail member 35.

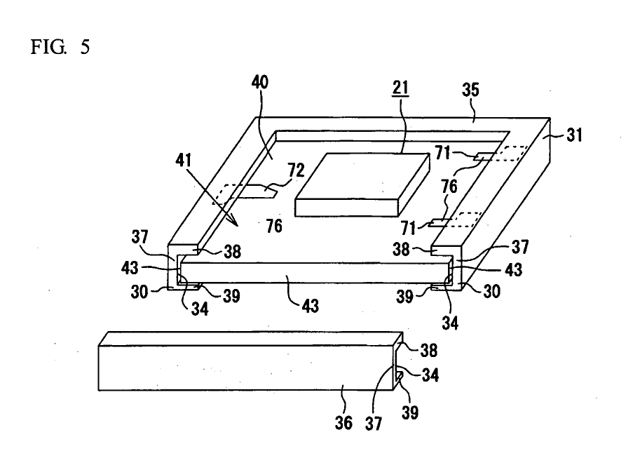

Next, the adhesive 50 is applied into the depression 34 of the rail member 35, and the resin wiring substrate 40 is inserted into the depression 34 (refer to FIG. 5). Moreover, the adhesive 50 is applied into the depression 34 of the rail member 36, and the adhesive is applied to end surfaces 30 (refer to FIG. 5) provided at both ends of the rail member 35. In addition, the adhesive to be applied to the end surfaces 30 is the same as the adhesive to be applied in the accommodating recesses 70 in the preferable aspect of the invention, and the adhesive 50 to be applied to the depression 34 in the invention. Then, both the ends (apical surfaces of the first protruding piece 38 and the second protruding piece 39) of the rail member 36 are brought into contact with both the ends (end surfaces 30) of the rail member 35, and the outer peripheral portion of the resin wiring substrate 40 is inserted into the depression 34 of the rail member 36. In this state, if the adhesive is dried and cured, the rail members 35 and 36 are connected to each other via the adhesive at their ends, thereby forming the rectangular frame-shaped stiffener 31. Further, the stiffener 31 is joined and fixed to the resin wiring substrate 40 by the drying and curing of the adhesive 50, whereby the semiconductor package 10 of the invention shown in FIG. 1 is obtained. In the preferable aspect of the invention, then, if the first protruding portions 76 of the plate-like connecting terminal pieces 71 and 72 are connected to the conductor layers (conductor layers 73 and 74) on the side of the substrate principal surface 41 via the solder 78, and the second protruding portions 77 of the plate-like connecting terminal pieces 71 and 72 are connected to the conductor layers (conductor layers 73 and 74) on the side of the substrate rear surface 42 via the solder 79, the semiconductor package 10 of the preferable aspect of the invention is obtained. In addition, since the adhesive which connects the rail members 35 and 36 to each other, the adhesive 50 which join and fixes the stiffener 31 to the resin wiring substrate 40, and the adhesive which attaches the plate-like connecting terminal pieces 71 and 72 to the rail member 35 in the preferable aspect of the invention is dried and cured at room temperature (in non-heated state), the resin wiring substrate 40 is not influenced by thermal stress.

Accordingly, according to this embodiment, the following effects can be obtained.

(1) According to the wiring substrate 11 with a stiffener of this embodiment, the stiffener 31 is surface-joined to a plurality of surfaces (the substrate principal surface 41, the substrate rear surface 42, the substrate side surfaces 43) at four sides of the resin wiring substrate 40. Thereby, since the four sides of the resin wiring substrate 40 can be reinforced surely, the warpage of the resin wiring substrate 40 is suppressed surely. Therefore, since the defects resulting from the warpage of the resin wiring substrate 40 are prevented, the reliability of the wiring substrate 11 with a stiffener improves. Moreover, since the resin wiring substrate 40 is hardly warped and thereby the substrate rear surface 42 becomes flat, the semiconductor package 10 can surely be mounted on a mother board. Further, since the stiffness of the wiring substrate 11 with a stiffener becomes high by the surface joining of the stiffener 31 to the resin wiring substrate 40, the handling ability of the wiring substrate 11 with a stiffener improves. Moreover, since the stiffener 31 has the depression 34, and has a shape where stiffness is higher than a mere flat plate shape, the need for making the stiffener 31 thick or forming the stiffener 31 using a material of high cost and high stiffness is obviated. Accordingly, the reliability and handling ability can be improved without increasing the manufacturing cost of the stiffener 31.

(2) The stiffener 31 of this embodiment is formed in a rectangular frame shape by connecting a plurality of rail members 35 and 36 to one another at their respective ends. Accordingly, since the stiffener 31 can be formed by the rail members 35 and 36 with a comparatively simple structure, the manufacturing cost of the stiffener 31 is further reduced.

(3) The protruding length of the first protruding piece 38 of this embodiment is about 2.0 mm, and the first protruding piece 38 merely covers only a part of the outer peripheral portion of the substrate principal surface 41. Consequently, since an exposed portion of the substrate principal surface 41 becomes large, not only the LSI chip 21 but electronic components other than the LSI chip 21 can be easily mounted on the substrate principal surface 41. Moreover, the protruding amount of the first protruding portions 76 of the plate-like connecting terminal pieces 71 and 72 provided in the preferable aspect of the invention is larger than the protruding amount of the first protruding piece 38. For this reason, even in a case where the LSI chip 21 (or electronic component) is disposed in a central portion of the substrate principal surface 41, the plate-like connecting terminal pieces 71 and 72 and the LSI chip 21 (or electronic component) can be electrically connected surely.

(4) In the wiring substrate 11 (wiring substrate 11 with a stiffener of the preferable aspect of the invention in which the plate-like connecting terminal pieces 71 and 72 are provided) with a stiffener of this embodiment, the stiffener 31 is configured to be surface joined to a plurality of surfaces (the substrate principal surface 41, the substrate rear surface 42, and the substrate side surfaces 43) at four sides of the resin wiring substrate 40. For this reason, it becomes easy to attach the plate-like connecting terminal pieces 71 and 72 to the stiffener 31 along the inside surface 33 of the stiffener 31. As a result, the conductor layers on the side of the substrate principal surface 41 (conductor layers 73 and 74), and the conductor layers on the side of the substrate rear surface 42 (conductor layers 73 and 74) can be electrically connected by bypassing the outside of the resin wiring substrate 40. Accordingly, large current can be supplied to the conductor layers (conductor layers 73 and 74) on the side of the substrate principal surface 41 via the plate-like connecting terminal pieces 71 and 72 from the conductor layers (conductor layers 73 and 74) on the side of the substrate rear surface 42 without changing the structure of the resin wiring substrate 40. Therefore, large current can be surely supplied to the LSI chip 21 electrically connected to the conductor layer 73 for a power source.

(5) Since the plate-like connecting terminal pieces 71 and 72 provided in the preferable aspect of the invention are made of a conductive metallic material of higher stiffness than a resin material which constitutes the resin wiring substrate 40, the four sides of the resin wiring substrate 40 can be reinforced not only by the stiffener 31 but by the plate-like connecting terminal pieces 71 and 72. Thereby, since the warpage of the resin wiring substrate 40 is suppressed more surely, and the defects resulting from the warpage are prevented more surely, the reliability of the wiring substrate 11 with a stiffener further improves.

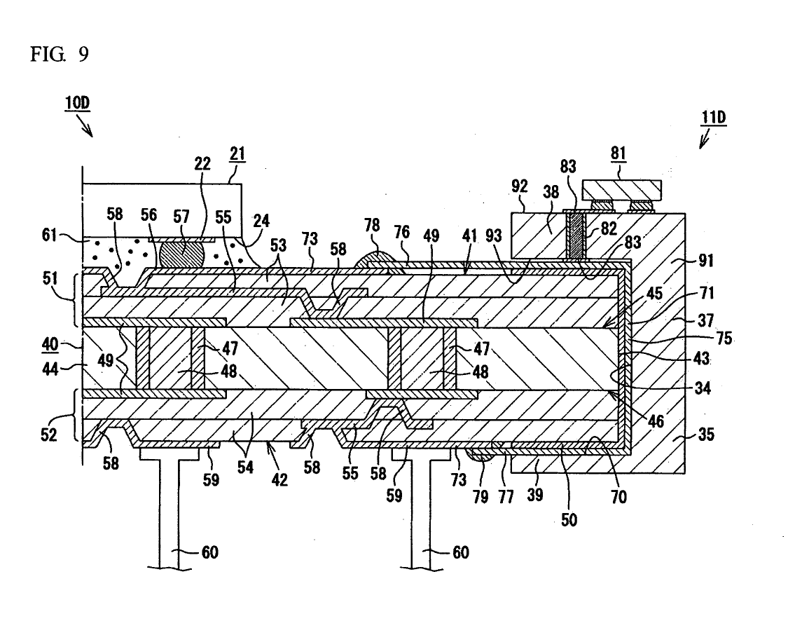

In addition, this embodiment may be modified as follows.
As shown in FIG. 9, a stiffener 91 in which electronic component 81 is mounted on an outside surface 92 may be provided in a wiring substrate 11D with a stiffener which constitutes a semiconductor package 10D. In this case, the stiffener 91 includes a through-hole conductor 82 (conductor post) which electrically connects a portion on the side of an inside surface 93 and a portion on the side of the outside surface 92, and terminal pads 83 which are arranged on the inside surface 93 and the outside surface 92 and are connected to the through-hole conductor 82. The plate-like connecting terminal piece 71 for a power source is connected to the terminal pad 83 arranged at the end of the through-hole conductor 82 on the side of the inside surface 93, and the electronic component 81 is connected to the terminal pad 83 arranged at the end of the through-hole conductors 82 on the side of the outside surface 92.

Thus, even if the electronic component 81 has a defect, the electronic component 81 can be remounted and the resin wiring substrate 40 does not become useless. In addition, as the electronic component, there are, for example, chips (for example, chip transistors, chip diodes, chip resistors, chip capacitors, chip coils, etc.) which have a plurality of terminals on a rear surface or side surfaces.
In the above embodiment, the spacing between the first protruding piece 38 and the second protruding piece 39 is a little larger than the thickness of the resin wiring substrate 40. However, the spacing between the first protruding piece 38 and the second protruding piece 39 may be made smaller than the thickness of the resin wiring substrate 40, and the resin wiring substrate 40 may be sandwiched by the first protruding piece 38 and the second protruding piece 39. Accordingly, the spacing between the first protruding portion 76 and the second protruding portion 77 may be made smaller than the thickness of the resin wiring substrate 40, and the resin wiring substrate 40 may be sandwiched by the first protruding portion 76 and the second protruding portion 77. Thus, even if the adhesive 50 is used, the stiffener 31 can be surely joined to the resin wiring substrate 40. Further, if the adhesive 50 is used, the joining between the resin wiring substrate 40 and the stiffener 31 becomes more positive.
The stiffener 31 of the above embodiment is composed of a plurality of rail members 35 and 36, and is formed in a rectangular frame shape by connecting the rail members 35 and 36 to each other at their respective ends. However, the stiffener 31 may be one rectangular frame-shaped member.

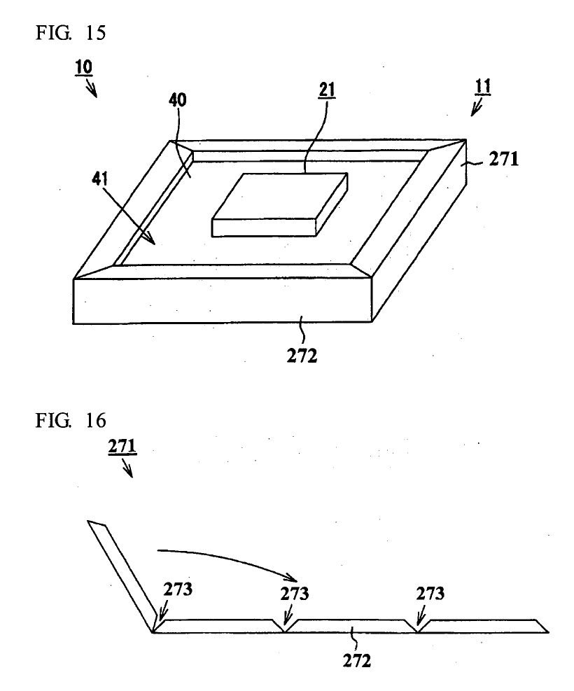

Further, as shown in FIGS. 15 and 16, a stiffener 271 formed in a rectangular frame shape by bending a rail-like member 272 having three bent portions 273 at every 90° at their respective bent portions 273 may be provided. In addition, three bent portions 273 are provided at regular intervals in the rail-like member 272. Thus, since the process of connecting the rail members 35 and 36 to each other like the above embodiment becomes unnecessary, manufacture of the stiffener 271 becomes easy.

Although the stiffener 31 of the above embodiment surrounds the four sides of the resin wiring substrate 40, the four sides does not need to be surrounded. In addition, the plate-like connecting terminal pieces 71 and 72 are provided in the preferable aspect of the invention, and are not components indispensable to the invention.

The wiring substrate 11 with a stiffener which constitutes the semiconductor package 10 of the above embodiment includes the stiffener 31 in which the protruding length of the first protruding piece 38 and the second protruding piece 39 are set equal to each other. In addition, although the substrate rear surface 42 has high strength since the pads 59 (and pins 60) for PGA are arranged almost the whole surface, the substrate principal surface 41 has low strength since the IC chip 21 is arranged in the central portion.

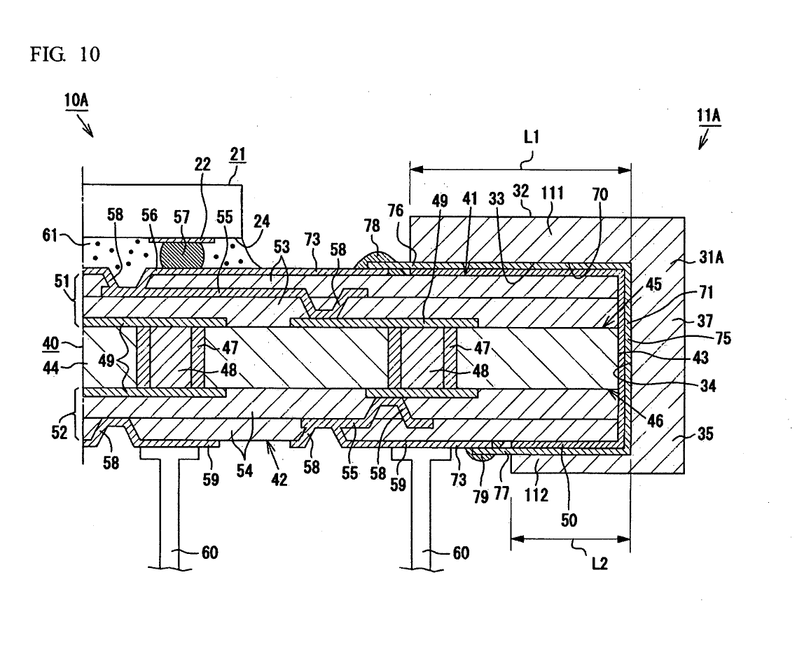

Thus, as shown in FIG. 10, a stiffener 31A in which the protruding amount L1 of a first protruding piece 111 is set to be larger than the protruding amount L2 of a second protruding piece 112 may be provided in a wiring substrate 11A with a stiffener which constitutes a semiconductor package 10A. Here, the protruding amount L1 of the first protruding piece 111 is set to 4 mm, and the protruding amount L2 of the second protruding piece 112 is set to 2 mm. Further, the first protruding piece 111 is set to be thicker than the second protruding piece 112. Specifically, the thickness of the first protruding piece 111 is set as 0.5 mm or more and 1.5 mm or less (1.0 mm in FIG. 10), and the thickness of the second protruding piece 112 is set to 0.05 mm or more and 0.5 mm or less (0.1 mm or more and 0.2 mm or less in FIG. 10). Thus, since the stiffness of the stiffener 31A becomes higher, the stiffness of the resin wiring substrate 40 further improves.

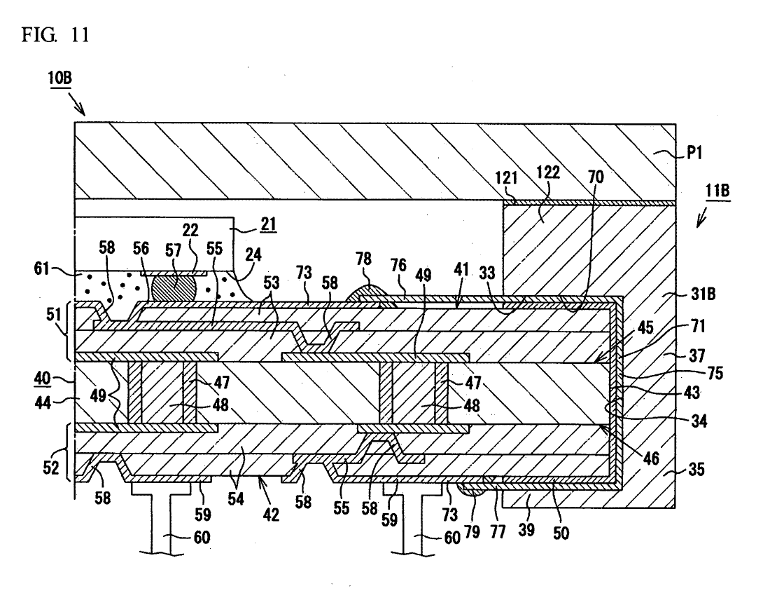

As shown in FIG. 11, a stiffener 31B may be provided in a wiring substrate 11B with a stiffener which constitutes a semiconductor package 10B, and a printed circuit board P1 may be set on an outside surface 121 (top surface) of the stiffener 31B. In addition, since the first protruding piece 122 of the stiffener 31B is set to be thicker than the height from the substrate principal surface 41 to the surface (top surface in FIG. 11) of the IC chip 21, the printed circuit board P1 will not come into contact with the IC chip 21. That is, the stiffener 31B has both the function to reinforce the resin wiring substrate 40 and the function as a spacer which is interposed between the resin wiring substrate 40 and the printed circuit board P1.

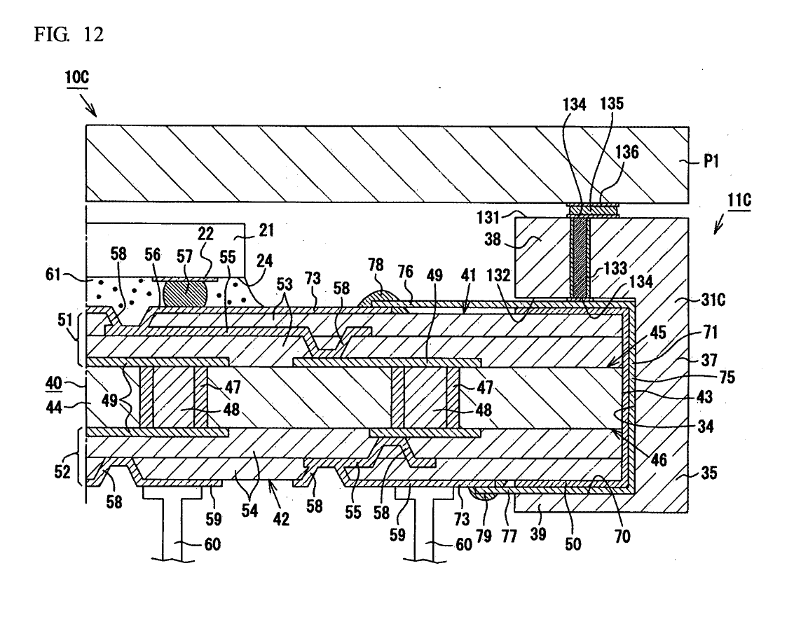

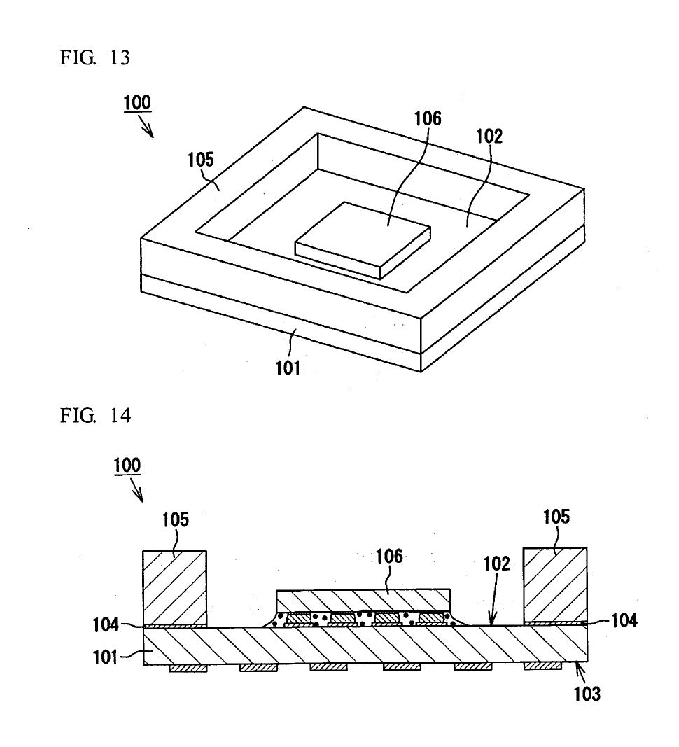

As shown in FIG. 12, a stiffener 31C may be provided in a wiring substrate 11C with a stiffener which constitutes a semiconductor package 10C, and the printed circuit board P1 may be set on the outside surface 131 (top surface) of the stiffener 31C. Moreover, a through-hole conductor 133 which electrically connects a portion on the side of the inside surface 132 and a portion on the side of the outside surface 131 may be provided in the stiffener 31C, terminal pads 134 which are arranged on the inside surface 132 and the outside surface 131 and are connected to the through-hole conductor 133 may be provided, and solder bumps 135 may be provided on the terminal pads 134. Thereby, the plate-like connecting terminal piece 71 for a power source on the side of the resin wiring substrate 40 and a substrate side terminal pad 136 of the printed circuit board P1 are electrically connected via the through-hole conductor 133, the terminal pads 134, and the solder bumps 135.
The stiffener 31 in the above embodiment is formed of polybutene resin. However, the stiffener 31 may be formed of other resin materials, and may be formed of a metallic material, such as invar (Fe—Ni-based alloys, 36% Ni), a ceramic material, etc. In a case where the stiffener 31 is formed of a metallic material, such as invar (Fe—Ni-based alloys, 36% nickel), in the wiring substrate with a stiffener of the preferable aspect of the invention in which the plate-like connecting terminal pieces 71 and 72 are provided, an insulating material is interposed between the stiffener 31 and the plate-like connecting terminal pieces 71 and 72. In addition, if the stiffener 31 is formed of a metallic material, the electromagnetic waves from static electricity or a noise source can be shielded by the stiffener 31.

Next, the technical ideas to be grasped by the above-mentioned embodiment are listed below.

(1) A semiconductor package including a wiring substrate with a reinforcing member including: a resin wiring substrate having a substrate principal surface, a substrate rear surface, and substrate side surfaces, forming a rectangular shape having four sides in plan view, and having a structure in which a resin insulating layer and a conductor layer are stacked, a reinforcing member formed in a rectangular frame shape which surrounds the four sides of the resin wiring substrate, and having a depression surface-joined to at least one of the substrate side surfaces, an outer peripheral portion of the substrate principal surface, and an outer peripheral portion of the substrate rear surface at its inner wall, and a semiconductor integrated circuit element mounted on at least one of the substrate principal surface and the substrate rear surface.

(2) A reinforcing member for a wiring substrate attached to a wiring substrate with a reinforcing member including: a resin wiring substrate having a substrate principal surface, a substrate rear surface, and substrate side surfaces, forming a rectangular shape having four sides in plan view, and having a structure in which a resin insulating layer and a conductor layer are stacked, and formed in a rectangular frame shape which surrounds the four sides of the resin wiring substrate. The reinforcing member is composed of a plurality of rail members having a depression capable of being surface-joined to at least one of the substrate side surfaces, an outer peripheral portion of the substrate principal surface, and an outer peripheral portion of the substrate rear surface at its one side surface, and is formed in a rectangular frame shape by connecting the plurality of rail members to each other at their respective ends.

(3) A reinforcing member for a wiring substrate attached to a wiring substrate with a reinforcing member including: a resin wiring substrate having a substrate principal surface, a substrate rear surface, and substrate side surfaces, forming a rectangular shape having four sides in plan view, and having a structure in which a resin insulating layer and a conductor layer are stacked, and formed in a rectangular frame shape which surrounds the four sides of the resin wiring substrate. The reinforcing member is composed of a plurality of rail members having a depression capable of being surface-joined to at least one of the substrate side surfaces, an outer peripheral portion of the substrate principal surface, and an outer peripheral portion of the substrate rear surface at its one side surface, and is formed in a rectangular frame shape by connecting the plurality of rail members to each other at their respective ends. The plurality of rail members are such that the depression is constituted by a reinforcing member main body, a first protruding piece that protrudes from the reinforcing member main body, and a second protruding piece which protrudes in the same direction as the first protruding piece from the reinforcing member main body. The spacing between the first protruding piece and the second protruding piece is smaller than the thickness of the resin wiring substrate. The resin wiring substrate is capable of being sandwiched by the first protruding piece and the second protruding piece.

(4) A semiconductor package including a wiring substrate with a reinforcing member including: a resin wiring substrate having a substrate principal surface, a substrate rear surface, and substrate side surfaces, forming a rectangular shape having four sides in plan view, and having a structure in which a resin insulating layer and a conductor layer are stacked, a reinforcing member arranged in portions of sides possessed by the resin wiring substrate, and having an inside surface surface-joined to at least one of the substrate side surfaces, an outer peripheral portion of the substrate principal surface, and an outer peripheral portion of the substrate rear surface, and a plate-like connecting terminal piece coming into contact with a conductor layer of the resin wiring substrate on the side of the substrate principal surface, and a conductor layer thereof on the side of the substrate rear surface, thereby electrically connecting the conductor layers, and a semiconductor integrated circuit element mounted on at least one of the substrate principal surface and the substrate rear surface.

(5) A reinforcing member with a connecting terminal piece attached to a resin wiring substrate having a substrate principal surface, a substrate rear surface, and substrate side surfaces, forming a rectangular shape having four sides in plan view, and having a structure in which a resin insulating layer and a conductor layer are stacked. The reinforcing member with a connecting terminal piece includes a reinforcing member capable of being arranged in portions of sides possessed by the resin wiring substrate, and having an inside surface surface-joined to at least one of the substrate side surfaces, an outer peripheral portion of the substrate principal surface, and an outer peripheral portion of the substrate rear surface, and a plate-like connecting terminal piece attached to the reinforcing member along the inside surface or outside surface of the reinforcing member, and coming into contact with a conductor layer on the side of the substrate principal surface and a conductor layer on the side of the substrate rear surface, thereby electrically connecting the conductor layers.

(6) A wiring substrate with a reinforcing member including a resin wiring substrate having a substrate principal surface, a substrate rear surface, and substrate side surfaces, forming a rectangular shape having four sides in plan view, and having a structure in which a resin insulating layer and a conductor layer are stacked, a reinforcing member arranged in portions of sides possessed by the resin wiring substrate, and having an inside surface surface-joined to at least one of the substrate side surfaces, an outer peripheral portion of the substrate principal surface, and an outer peripheral portion of the substrate rear surface, and a plate-like connecting terminal piece attached to the reinforcing member along the inside surface or outside surface of the reinforcing member, and coming into contact with a conductor layer of the resin wiring substrate on the side of the substrate principal surface and a conductor layer thereof on the side of the substrate rear surface, thereby electrically connecting the conductor layers. The reinforcing member is composed of a plurality of rail members, and is formed in a rectangular frame shape by connecting the plurality of rail members to each other at their respective ends.

Although the invention has been described above in relation to preferred embodiments and modifications thereof, it will be understood by those skilled in the art that other variations and modifications can be effected in these preferred embodiments without departing from the scope and spirit of the invention.

What is claimed is:

1. A wiring substrate with a reinforcing member comprising:
a resin wiring substrate having a substrate principal surface, a substrate rear surface, and substrate side surfaces, forming a rectangular shape having four sides in plan view, and comprising a resin insulating layer and a conductor layer; and
a reinforcing member formed in a rectangular frame shape which surrounds the four sides of the resin wiring substrate, and provided with an inner wall having a depression surface-joined to at least one of the substrate side surfaces, an outer peripheral portion of the substrate principal surface, and an outer peripheral portion of the substrate rear surface.

2. The wiring substrate with a reinforcing member according to claim 1, wherein the reinforcing member comprises a plurality of rail members, and is formed in a rectangular frame shape by connecting the plurality of rail members to each other at respective ends of the rail members.

3. The wiring substrate with a reinforcing member according to claim 1, wherein the reinforcing member is a rail-like member, and is formed in a rectangular frame shape by bending three bent portions provided in the rail-like member.

4. The wiring substrate with a reinforcing member according to claim 2, wherein the inner wall of the depression is joined and fixed to at least one of the substrate side surfaces, the outer peripheral portion of the substrate principal surface, and the outer peripheral portion of the substrate rear surface via adhesive.

5. The wiring substrate with a reinforcing member according to claim 1,
wherein the reinforcing member is configured such that the depression is constituted by a reinforcing member main body capable of coming into surface contact with the substrate side surfaces, a first protruding piece capable of protruding toward a center of the resin wiring substrate from the reinforcing member main body and coming into surface contact with the outer peripheral portion of the substrate principal surface, and a second protruding piece capable of protruding toward the center of the resin wiring substrate from the reinforcing member main body and coming into surface contact with the outer peripheral portion of the substrate rear surface, and
the second protruding piece has a thickness smaller than a thickness of the first protruding piece.

6. The wiring substrate with a reinforcing member according to claim 1,
wherein the reinforcing member is configured such that the depression is constituted by a reinforcing member main body capable of coming into surface contact with the substrate side surfaces, a first protruding piece capable of protruding toward a center of the resin wiring substrate from the reinforcing member main body and coming into surface contact with the outer peripheral portion of the substrate principal surface, and a second protruding piece capable of protruding toward the center of the resin wiring substrate from the reinforcing member main body and coming into surface contact with the outer peripheral portion of the substrate rear surface,
a spacing between the first protruding piece and the second protruding piece is smaller than a thickness of the resin wiring substrate, and
the resin wiring substrate is sandwiched by the first protruding piece and the second protruding piece.

7. The wiring substrate with a reinforcing member according to claim 5, wherein a protruding amount of the first protruding piece is larger than a protruding amount of the second protruding piece.

8. The wiring substrate with a reinforcing member according to claim 6, wherein a protruding amount of the first protruding piece is larger than a protruding amount of the second protruding piece.

9. The wiring substrate with a reinforcing member according to claim 1, wherein the reinforcing member is made from a resin material of higher stiffness than a resin material which constitutes the resin wiring substrate.

10. The wiring substrate with a reinforcing member according to claim 1, further comprising a plate-like connecting terminal piece attached to the reinforcing member along an inside surface or an outside surface of the reinforcing member, and coming into contact with conductor layers of the resin wiring substrate on a side of the substrate principal surface and the conductor layers on a side of the substrate rear surface, so as to electrically connect the conductor layers.

11. The wiring substrate with a reinforcing member according to claim 10, wherein the plate-like connecting terminal piece is attached to the reinforcing member along the inside surface of the reinforcing member, a portion of the inside surface of the reinforcing member is formed with an accommodating recess for accommodating the plate-like connecting terminal piece, and a depth of the accommodating recess is equal to a thickness of the plate-like connecting terminal pieces.

12. The wiring substrate with a reinforcing member according to claim 10, wherein the plate-like connecting terminal piece comes into contact with the conductor layers for a power source formed on the substrate principal surface and the substrate rear surface, or the conductor layers for grounding formed on the substrate principal surface and the substrate rear surface to be electrically connected thereto.

13. The wiring substrate with a reinforcing member according to claim 10, wherein a plurality of the plate-like connecting terminal pieces are provided, and the reinforcing member is made from an insulated resin material.

14. The wiring substrate with a reinforcing member according to claim 10, wherein the reinforcing member is made from a resin material of higher stiffness than a resin material which constitutes the resin wiring substrate, and the plate-like connecting terminal piece is made from a conductive metallic material of higher stiffness than the resin wiring substrate.

15. The wiring substrate with a reinforcing member according to claim 10, wherein the inside surface of the reinforcing member is partially stuck on the plate-like connecting terminal piece via adhesive, and is joined and fixed to at least one of the substrate side surfaces, an outer peripheral portion of the substrate principal surface, or an outer peripheral portion of the substrate rear surface via the adhesive.

16. The wiring substrate with a reinforcing member according to claim 10, wherein the reinforcing member is constituted by a reinforcing member main body capable of coming into surface contact with the substrate side surfaces, a first protruding piece capable of protruding toward a center of the resin wiring substrate from the reinforcing member main body and coming into surface contact with the outer peripheral portion of the substrate principal surface, and a second protruding piece capable of protruding toward the center of the resin wiring substrate from the reinforcing member main body and coming into surface contact with the outer peripheral portion of the substrate rear surface,
the plate-like connecting terminal piece is constituted by a terminal piece main body capable of coming into contact with the substrate side surfaces and the reinforcing member main body, a first protruding portion capable of protruding toward the center of the resin wiring substrate from the terminal piece main body and coming into surface contact with the outer peripheral portion of the substrate principal surface and the first protruding piece, and a second protruding portion capable of protruding toward the center of the resin wiring substrate from the terminal piece main body and coming into surface contact with the outer peripheral portion of the substrate rear surface and the second protruding piece,
a protruding amount of the first protruding portion is larger than a protruding amount of the first protruding piece, and
a protruding amount of the second protruding portion is larger than a protruding amount of the second protruding piece.

17. The wiring substrate with a reinforcing member according to claim 16, wherein the protruding amount of the first protruding piece is larger than the protruding amount of the second protruding piece.

18. The wiring substrate with a reinforcing member according to claim 10,
wherein the reinforcing member comprises a conductor post which electrically connects a portion on the side of the inside surface and a portion on the side of the outside surface, and a terminal pad arranged on the outside surface, and connected to the conductor post, and
the plate-like connecting terminal piece is connected to the end of the conductor post on the side of the inside surface.
